(19) United States
(12) Patent Application Publication
(10) Pub. No.: US 2015/0189780 A1
(43) Pub. Date: Jul. 2, 2015

(54) CASE FOR A PORTABLE ELECTRONIC DEVICE HAVING AN INTERFACE TO PROVIDE FOR TRANSMISSION OF DATA BEWTEEN THE PORTABLE ELECTRONIC DEVICE AND AN EXTERNAL DEVICE

(71) Applicant: AFC TRIDENT, INC., Ontario, CA (US)

(72) Inventors: Yi-Chieh SU, Chino, CA (US); Hong Lip YOW, Chino, CA (US)

(21) Appl. No.: 14/583,549

(22) Filed: Dec. 26, 2014

Related U.S. Application Data
(63) Continuation-in-part of application No. 14/088,305, filed on Nov. 22, 2013.

(51) Int. Cl. H05K 5/02; H05K 5/00; H05K 5/03; H05K 7/02

(52) U.S. Cl. CPC H05K 5/0247; H05K 7/026; H05K 5/0086; H05K 5/0004; H05K 5/03

(57) ABSTRACT

Provided is a case for a portable electronic device including a first surface, a second surface, and sides between the first surface and the second surface, wherein the portable electronic device has an input socket and is adapted to electrically connect to an external electronic device. The case includes a cover portion adapted to couple to the first surface of the portable electronic device; a first interface at a first location on the cover portion to electrically couple to the input socket of the portable electronic device; a second interface at a second location on the cover portion adapted to electrically couple to the external electronic device; and a cable coupled to the first and second interfaces adapted to transmit data between the first interface and the second interface.

### CROSS-REFERENCE TO RELATED APPLICATIONS

This application is a continuation-in-part of U.S. patent application Ser. No. 14/088,305, filed Nov. 22, 2013, which patent application is incorporated herein by reference in its entirety.

### BACKGROUND OF THE INVENTION

1. Field of the Invention

The present invention relates to a case for a case for a portable electronic device having an interface to provide for transmission of data between the portable electronic device and an external device.

2. Description of the Related Art

Cases for portable electronic devices, such as smartphones, computer tables, and hand held digital music players provide a protective cover to absorb shock when the covered device is dropped or subject to damaging forces.

Certain Smartphone or portable electronic device cases, such as the AFC Trident Adaptive Modular System (A.M.S.®) cases for smartphones and tablets, provide a structure on the back cover portion of the case to allow the case to attach to different types of interchangeable accessories, such as windshield mount, bike mount, tripod mount, clamp, universal clip, cord management system. This allows the case to adapt the smartphone to different types of environments. (A.M.S. is a registered trademark in the United States of AFC Trident, Inc.)

### SUMMARY

Provided is a case for a portable electronic device including a first surface, a second surface, and sides between the first surface and the second surface, wherein the portable electronic device has an input socket and is adapted to electrically connect to an external electronic device. The case includes a cover portion adapted to couple to the first surface of the portable electronic device; a first interface at a first location on the cover portion to electrically couple to the input socket of the portable electronic device; a second interface at a second location on the cover portion adapted to electrically couple to the external electronic device; and a cable coupled to the first and second interfaces adapted to transmit data between the first interface and the second interface.

Further provided 12 is a case for a portable electronic device including a first surface, a second surface, and sides between the front surface and the back surface, wherein the portable electronic device includes an input socket and is adapted to electrically connect to an external electronic device and wherein the case is adapted to attach to an external structure. The case includes a cover portion having an inner surface and outer surface, wherein the inner surface is adapted to couple to the first surface of the portable electronic device; a first interface at a first location on the cover portion adapted to electrically couple to the input jack of the portable electronic device; a second interface at a second location on the cover to electrically couple to the external electronic device; an attachment structure formed on the outer surface of the cover portion and adapted to attach the cover portion to the external structure, wherein the external electronic device is electrically coupled to the second interface when the external structure is coupled to the attachment structure; and a cable coupled to the first and second interfaces adapted to transmit data between the first interface and the second interface.

Further provided is a case for a portable electronic device including a first surface, a second surface, and sides between the front surface and the back surface, wherein the portable electronic device has an input socket and is adapted to electrically connect to an external electronic device. The case includes a cover portion adapted to attach to the portable electronic device, wherein the cover portion has an inner surface adapted to contact the first surface of the portable electronic device and an outer surface; an elevated rim located on the inner surface of the cover portion, wherein the elevated rim has a sidewall extending from the inner surface to an upper surface of the elevated rim; a first interface on a side of the cover portion adapted to electrically couple to the input socket of the portable electronic device; a recessed region defined by the sidewalls of the elevated rim and the inner surface of the cover portion; a second interface having a connector at on the outer surface of the cover portion, wherein the connector is adapted to couple to the external electronic device; and a cable coupled to the first interface and the second interface, wherein the cable extends through the recessed region.

Further provided is a method for attaching a case to a portable electronic device, wherein the portable electronic device has a first surface, a second surface, and sides between the first surface and the second surface, and an input socket, comprising: attaching a cover portion to the first surface of the portable electronic device; adjusting a first interface at a first location on the cover portion to engage the input socket of the portable electronic device; coupling an external device to a second interface at a second location on the cover portion adapted to electrically couple the portable electronic device and the external electronic device, wherein a cable coupled to the first and second interfaces is adapted to transmit data between the first interface and the second interface.

### BRIEF DESCRIPTION OF THE DRAWINGS

Embodiments are described by way of example, with reference to the accompanying drawings, which are not drawn to scale, wherein:

FIGS. 1a, 1b, 1c, 1d, and 1e illustrate a first embodiment of a case for a portable electronic device.

FIGS. 2a and 2b illustrate a second embodiment of a case for a portable electronic device.

FIGS. 3a and 3b illustrate a third embodiment of a case for a portable electronic device.

FIGS. 4a and 4b illustrate a fourth embodiment of a case for a portable electronic device.

FIGS. 5a and 5b illustrate a fifth embodiment of a case for a portable electronic device.

FIGS. 6a and 6b illustrate a sixth embodiment of a case for a portable electronic device.

FIGS. 7a, 7b, 7c, 7d, and 7e illustrate a seventh embodiment of a case for a portable electronic device.

FIGS. 8a and 8b illustrate an embodiment of materials used for the case.

FIGS. 9a and 9b illustrate an eighth embodiment of a case for a portable electronic device.

### DETAILED DESCRIPTION

Embodiments provide a case having a cover portion to couple to a portable electronic device. The case has an electronic interface to couple to the portable electronic device at one location on the case and an electronic interface at another location on the case to electrically couple to an external device with which the portable electronic device may transmit data and/or power. In further embodiments, a cable is provided in the case to connect the portable electronic device interface and the external device interface at different locations on the case.

With the described embodiments, the electrical coupling to the external device can be located on a portion of the case most suitable for coupling to the particular external device irrespective of the location of the interface to the portable electronic device, which is typically determined by the portable electronic device manufacturer's specifications. With described embodiments, a cable located in the case connects the two interfaces to provide data and power transmission between the external device and the portable electronic device in the case.

Reference below will be made to the drawings wherein like structures may be provided with like reference designations. In order to show the structures of various embodiments most clearly, the drawings included herein include diagrammatic representations of components of a case and an electronic device. Thus, the actual appearance of the case and electronic device structures may appear different while still incorporating the claimed structures of the illustrated embodiments. Moreover, the drawings may show only the structures necessary to understand the illustrated embodiments. Additional structures known in the art have not been included to maintain the clarity of the drawings.

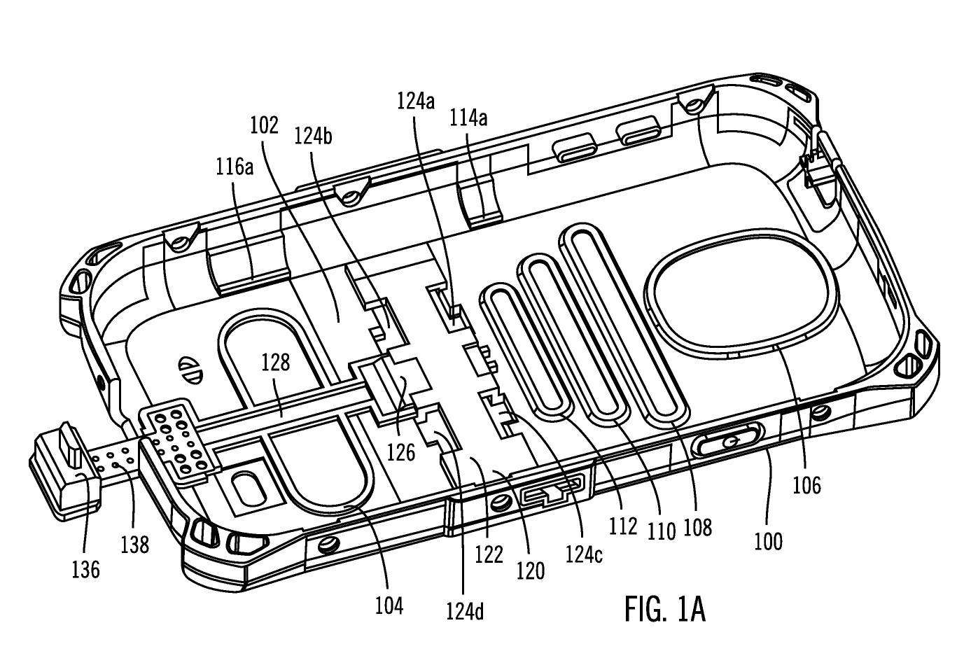

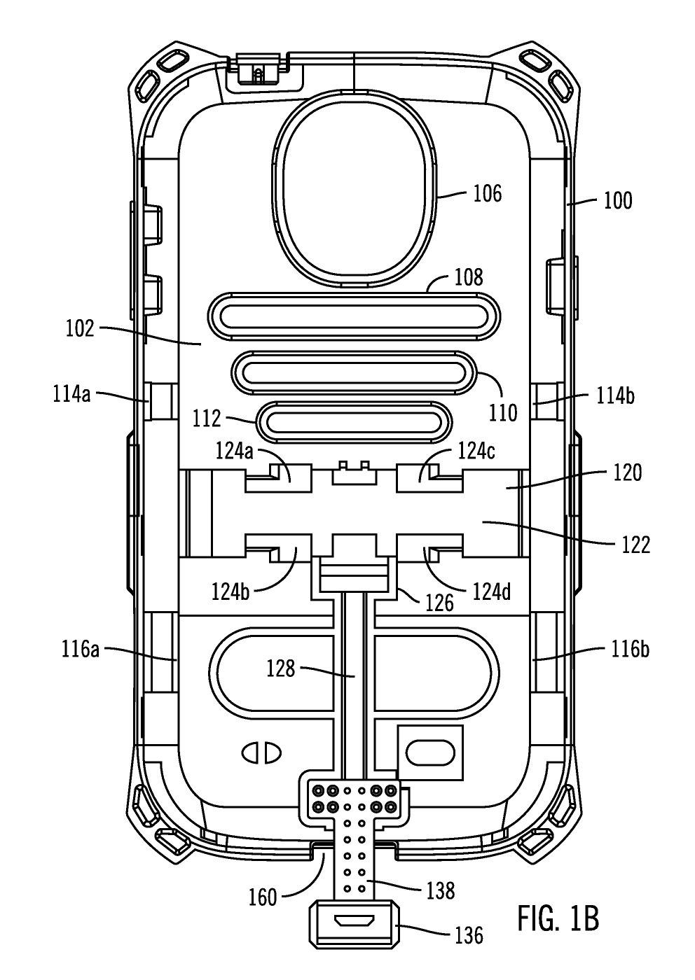

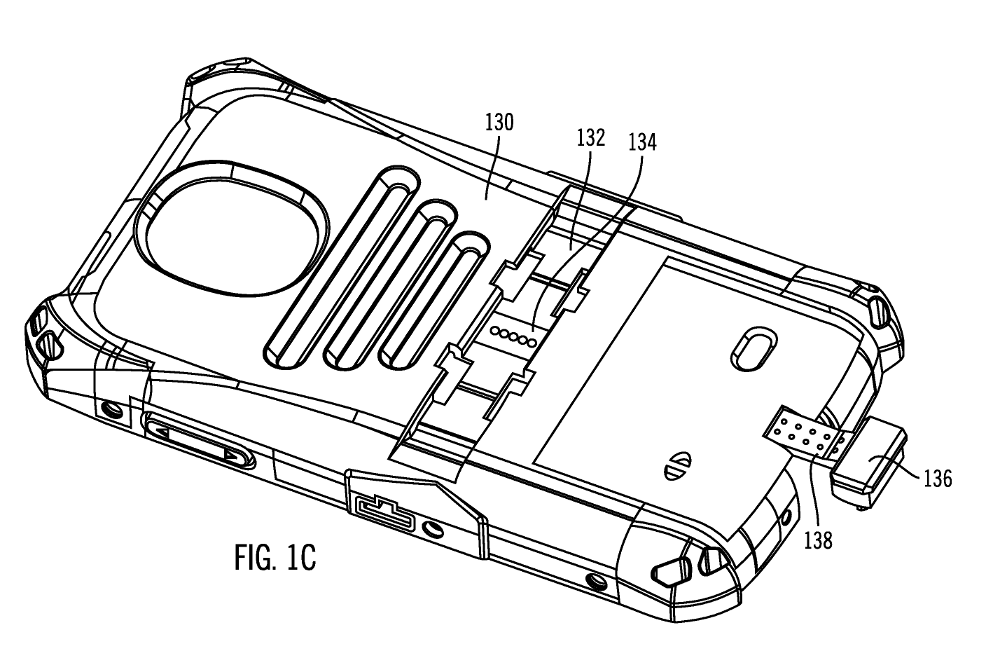

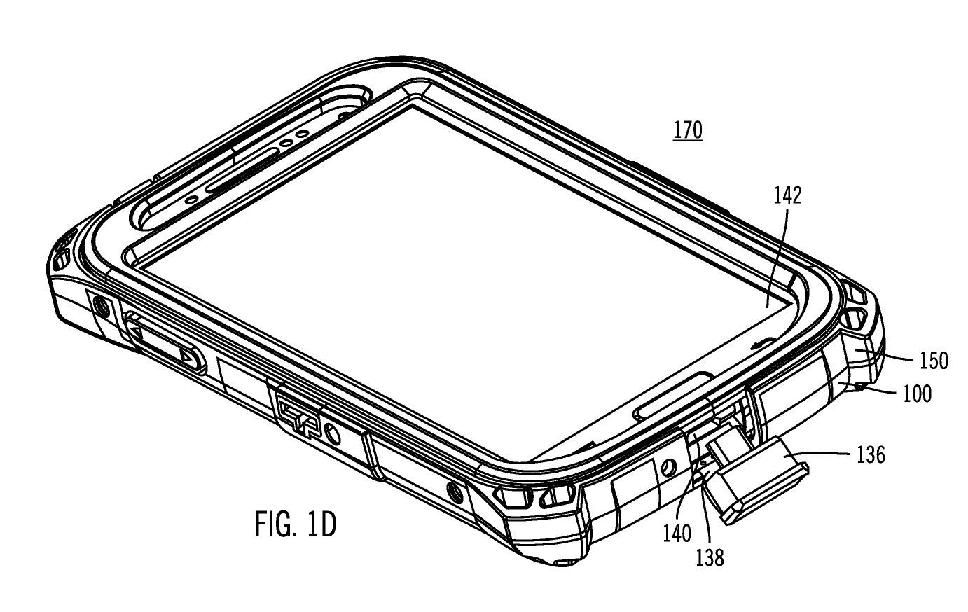

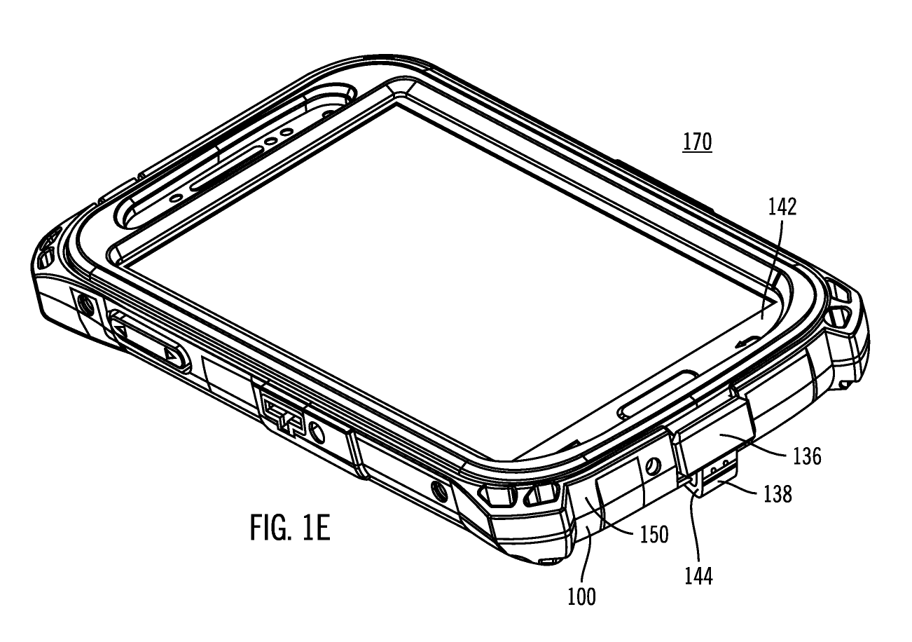

FIGS. 1a, 1b, 1c, 1d, and 1e illustrate different views of a first embodiment of a cover portion 100 of a case for a portable electronic device, such as a smart phone, held computer, media player, computer tablet, etc. The cover portion 100 may be adapted to attach to a back of the portable electronic device. As shown in FIGS. 1a and 1b, an inner surface 102 of the cover portion includes various elevated structures 104, 106, 108, 110, 12, 114, 116 that extend outward from the inner surface 102. These elevated structures 104, 106, 108, 110, 112, 114, 116 have sidewalls extending from an upper surface of the elevated structure to the inner surface 102 of the cover portion 100. In certain embodiments, the elevated structures' sidewalls are orthogonal to the inner surface 104 of the case and orthogonal to the upper surface of the elevated structure.

A recessed region is defined by the sidewalls of the elevated structures 104, 106, 108, 110, 112, 114, 116, the inner surface 102 and a back surface of the portable electronic device when the portable electronic device is coupled to the cover portion 102.

FIGS. 1a and 1b show an inner side 120 of an attachment structure 122 that has openings 124a, 124b, 124c, 124d to attach the cover portion 102 to an external structure, such as different modular units that are adapted to attach to the case 100 to provide a stand, holder, mount or attachment structure to connect to an external electronic device. The external electronic device may comprise a display monitor, audio speakers, projector, video game console, entertainment console, exercise equipment, Input/Output (I/O) device (e.g., an external keyboard, mouse, touch screen), power source, or other external electronic devices that may be connected to a portable electronic device, such as a smartphone or tablet.

An external interface 126 is integrated with the attachment structure 122 to electrically couple to the external electronic device. The external interface 126 has an internal connector (not shown) within the interface 126 that connects to a cable 128. FIG. 1c shows on outer surface 130 of the cover portion 100 and outer side 132 of the attachment structure 122. The external interface 126 has an external connector 134 on the outer side 132 of the attachment structure 122, shown as contact pads in FIG. 1c, to electrically couple to an external electronic device or cable or wire connected to the external electronic device. The external connector 134 is shown comprising a certain number of contact pads. In alternative embodiments, there may be a different arrangement and/or number of contact pads as well as an different connector configuration, such as a male or female connection port.

The cable 128 (FIGS. 1a, 1b) on the inner surface 102 includes electrical wiring to electrically connect a device interface 136 that is designed to connect to an electrical interface on the portable electronic device. The device interface 136 is in electrical communication with the external interface 126 (FIG. 1b) via the cable 128 to allow the transmission of data and/or power between the interfaces 126 and 136.

The cable 128 has a flexible portion 138 that extends through an opening 160 (FIG. 1b) in the case 100 and connects to the portable electronic device interface 136. The flexible portion 138 may flex in a substantially 90 degree angle to allow the external interface 136 to be pushed toward the interface of the portable electronic device in the case 100. For instance, FIGS. 1a, 1b, and 1c show the flexible portion 138 in an extended state where force is not exerted on the flexible portion 138. FIG. 1d shows the device interface 136 being moved upward, by application of an external force, toward an interface 140 on the portable electronic device 142, such as a smartphone. FIGS. 1d and 1e shows the flexible portion 138 flexed with the application of external force in a substantially 90 degrees 144 to allow the device 136 interface to electrically couple to the interface 140 of the portable electronic device 142.

In an alternative embodiment the external interface 136 may be affixed or integrated with the back cover portion 100, and remain in a fixed position when mating with the portable electronic device 142 when coupled to the case 100. In a further embodiment, the external interface 136 may comprise a head that is adapted to rotate to mate with the portable electronic device 142 before or after attaching the back cover portion 100 to the device 142.

FIGS. 1d and 1e further show a front cover portion 150 of the case coupled to the back cover portion 100 forming a case 170 covering the front and back portions of the portable electronic device 142.

In one embodiment, the cable 128, and interfaces 126, 136 may support transmission of data and power using Universal Serial Bus (USB) interface, the Apple Inc. Lightning proprietary interface, or other bus interfaces for the transmission of data and/or power. (Apple is a registered trademark of the Apple Corporation in the United States and other countries)

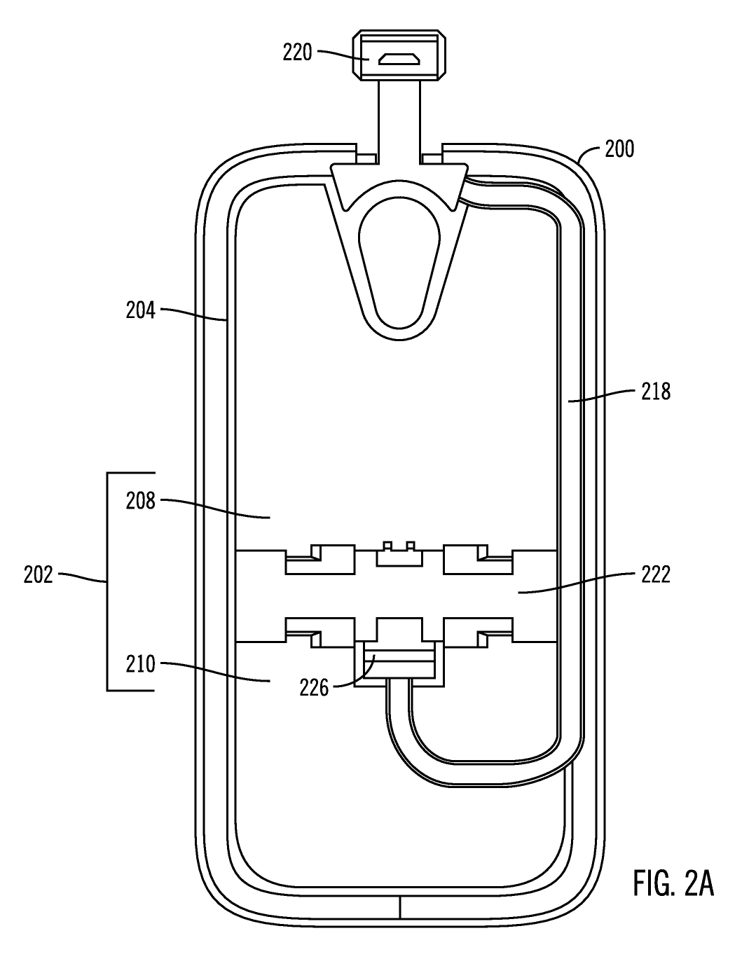

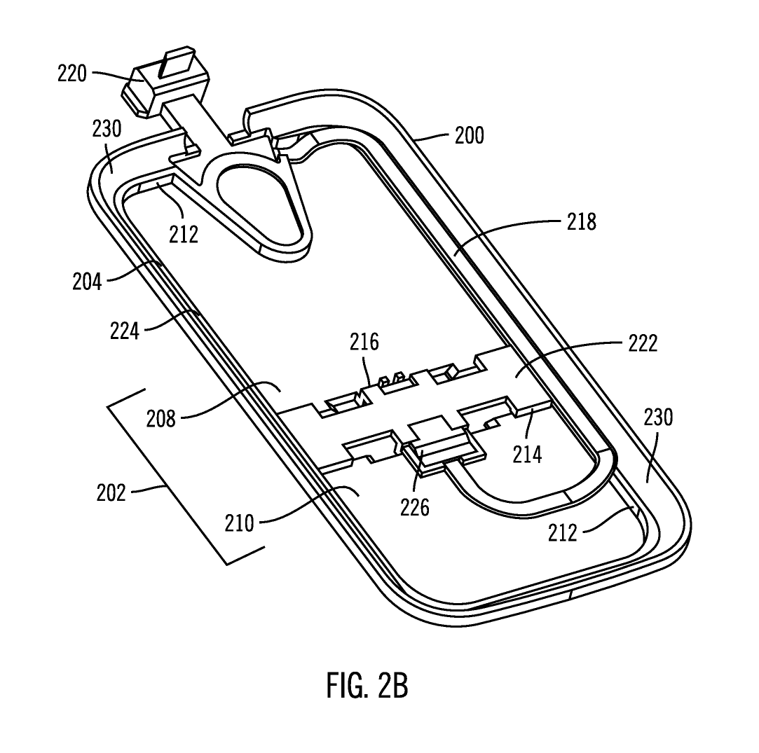

FIGS. 2a and 2b illustrate a second embodiment of a back cover portion 200 having an inner surface 202 with an elevated rim 204 extending around the inner surface 202. An attachment structure 222, such as described with respect to element 122 in FIGS. 1a-1e, separates the inner surface 202 area into two recessed regions 208, 210. The recessed regions 208, 210 form recessed spaces that are bounded by the inner surface 202, a sidewall 212 (FIG. 2b) of the elevated rim 204, sidewalls 214, 216 (FIG. 2b) of the attachment structure 222 and a back surface of the portable electronic device when coupled with the back cover portion 200. A cable 218 extends from an external device interface 226 downward and then turns in an orthogonal direction toward a side of the case 200, and then turns in a further orthogonal direction along the elevated rim 204 on the side of the case 200 through the recessed region 210, and then continues along the sidewall 212 through the recessed region 208 to provide an electrical connection between the device interface 220 of the portable electronic device and the external device interface 226. In the embodiment of FIGS. 2a and 2b, an upper surface 224 of the rim 204 is adapted to contact the portable electronic device when the case 200 is attached to the portable electronic device.

FIG. 2b further shows a curved surface 230 extending outward at an angle from a top surface of the rim 204 around the sides of the back cover portion 200. A back surface of the portable electronic device is in contact with the curved surface 230 and the upper surface of the rim 204 when the back portion 200 is coupled to the portable electronic device.

In alternative embodiments, the surface 230 may have shapes other than curved, such as angular, and may be designed to conform to the back surface and sides of the portable electronic device.

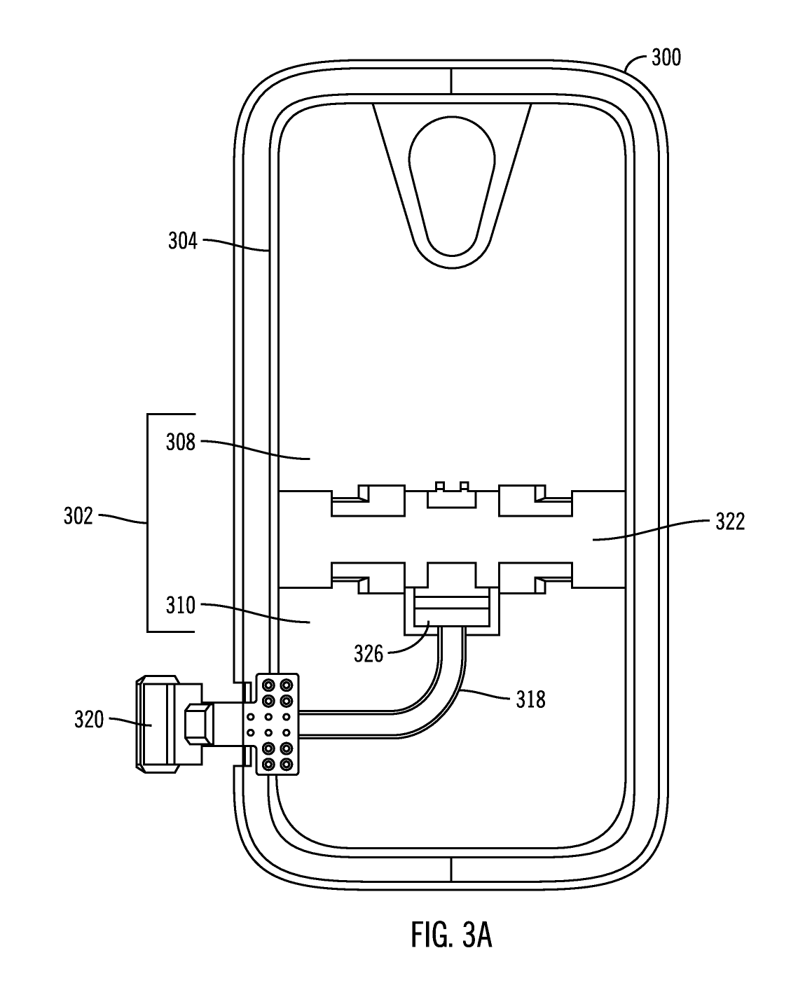

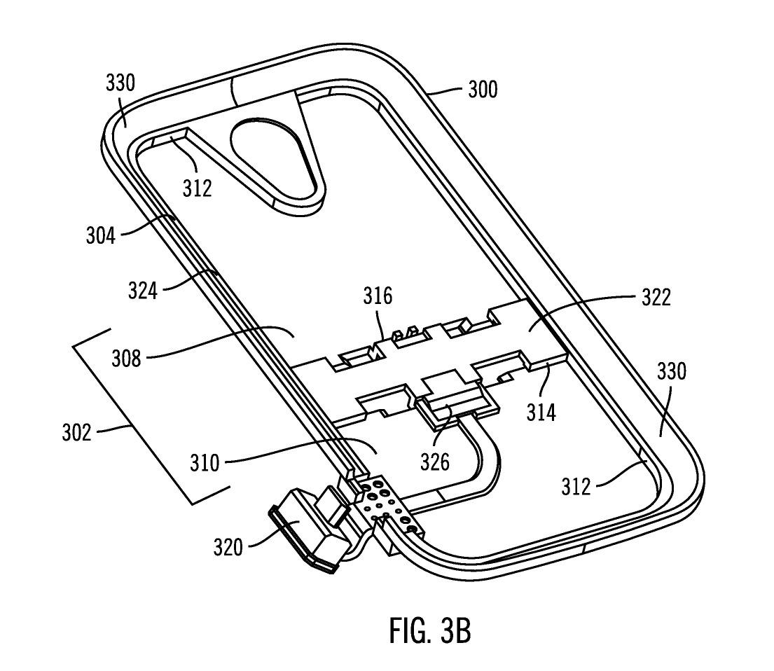

FIGS. 3a and 3b illustrate a third embodiment of a back cover portion 300 having elements 300, 302, 304, 308, 310, 312, 314, 316, 318, 320, 322, 326, 324, 330 that correspond to the case elements 200, 202, 204, 208, 210, 212, 214, 216, 218, 220, 222, 226, 224, 230, respectively, described with respect to FIGS. 2a and 2b, with the difference being in the position of the cable 218 and 318. In the embodiment of FIGS. 3a and 3b, the cable 318 extends through only the lower recessed region 310, and the cable 318 extends downward and then at a 90 degree angle toward the device interface 320 reflecting a different location for the device interface 320 than with respect to the embodiments of FIGS. 1a-1e, 2a, and 2b. The location of the device interface 320 is determined by the location of the connection on the portable electronic device with which the interface 320 couples.

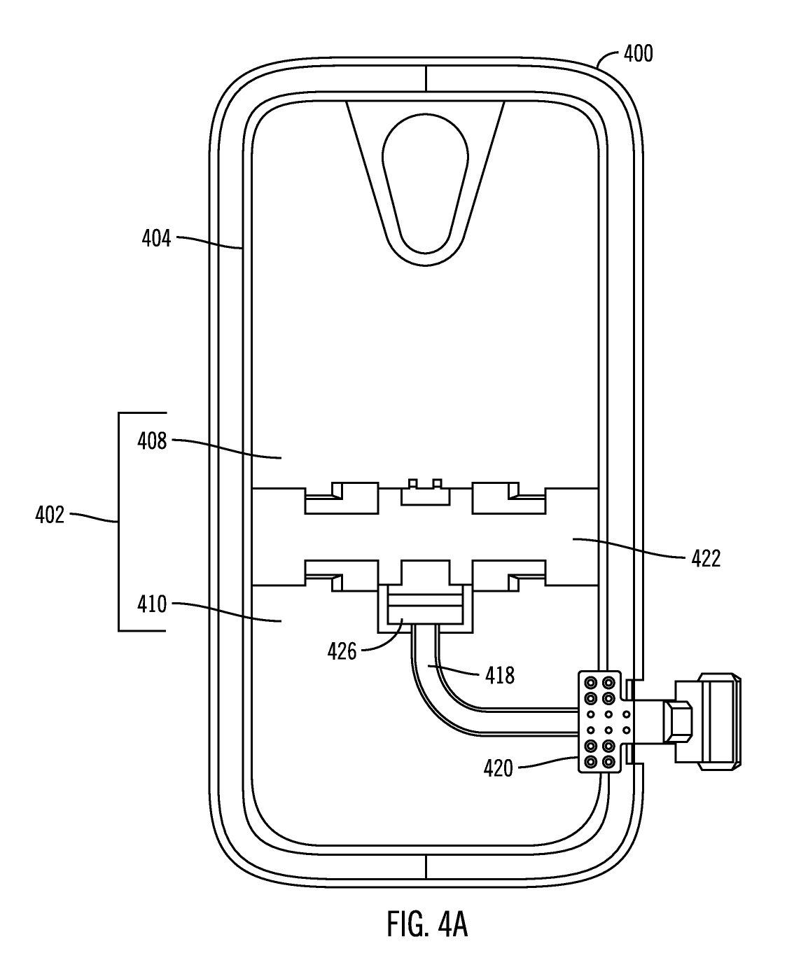

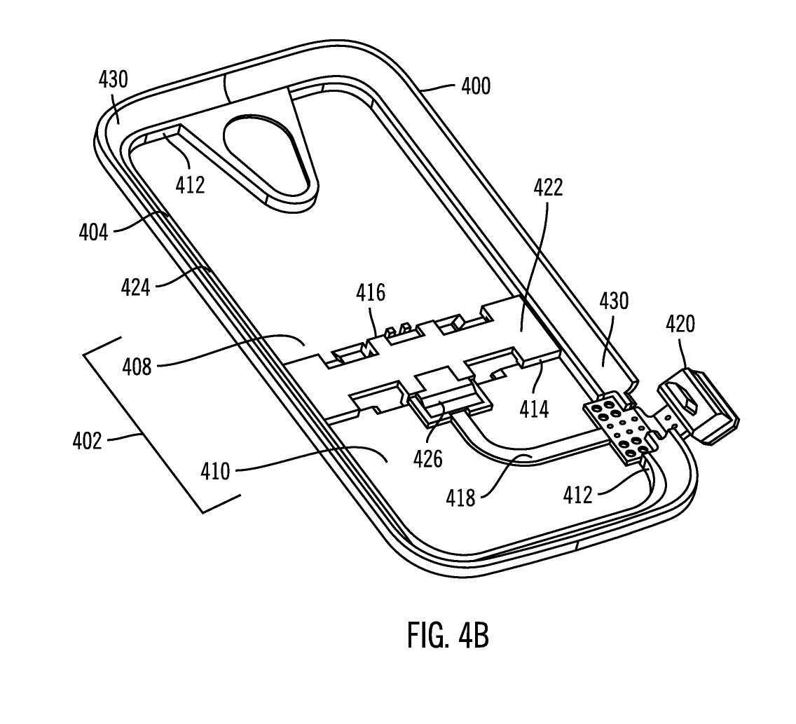

FIGS. 4a and 4b illustrate a fourth embodiment of a back cover portion 400 having elements 400, 402, 404, 408, 410, 412, 414, 416, 418, 420, 422, 426, 424, 430 that correspond to: case elements 300, 302, 304, 308, 310, 312, 314, 316, 318, 320, 322, 326, 324, 330, described with respect to FIGS. 3a and 3b; and case elements 200, 202, 204, 208, 210, 212, 214, 216, 218, 220, 222, 226, 224, 230, described with respect to FIGS. 2a and 2b, with the difference being in the position of the cable 218, 318, and 418. In the embodiment of FIGS. 4a and 4b, the cable 418 extends through only the lower recessed region 410, and the cable 418 extends downward and then at a 90 degree angle toward the device interface 420 reflecting a different location for the device interface 420 than shown with respect to the embodiments of FIGS. 1a-1e, 2a, 2b, 3a, and 4b.

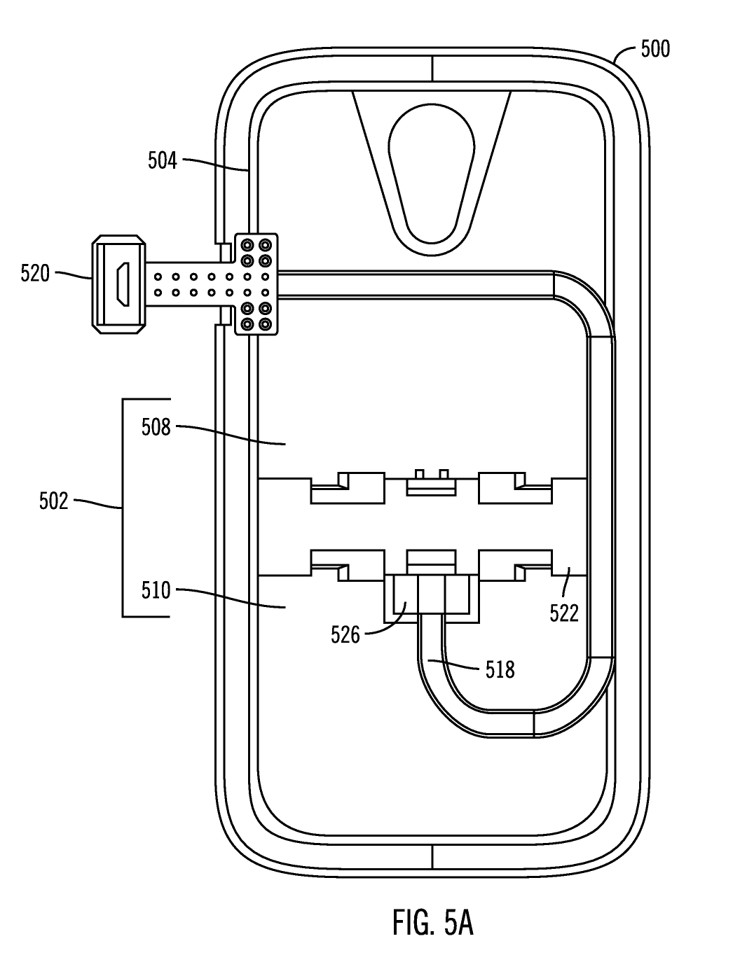

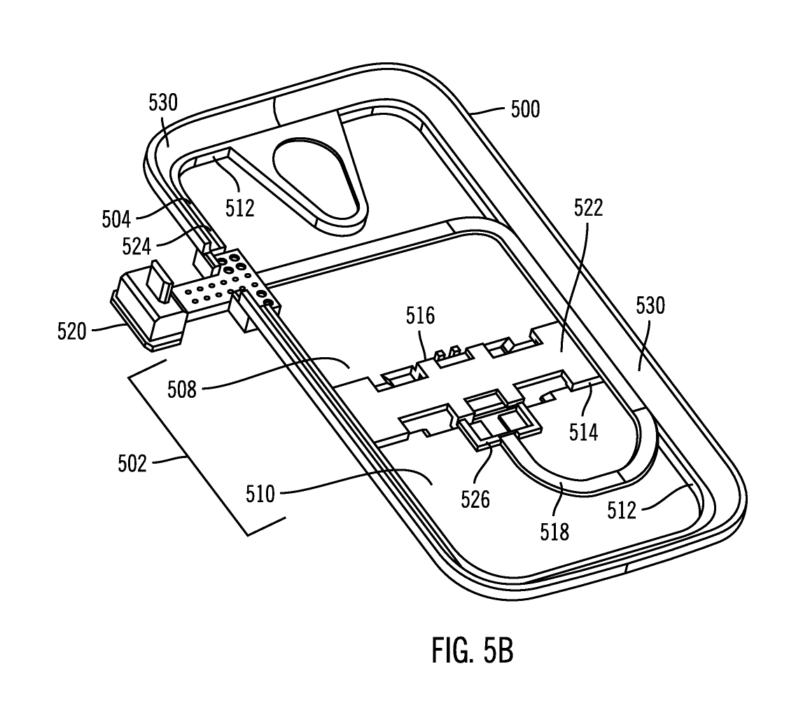

FIGS. 5a and 5b illustrate a fifth embodiment of a back cover portion 500 having elements 500, 502, 504, 506, 508, 510, 512, 514, 516, 518, 520, 522, 526, 524, 530 that correspond to: case elements 400, 402, 404, 408, 410, 412, 414, 416, 418, 420, 422, 426, 424, 430 described with respect to FIGS. 4a and 4b; case elements 300, 302, 304, 308, 310, 312, 314, 316, 318, 320, 322, 323, 324, 330, described with respect to FIGS. 3a and 3b; and case elements 200, 202, 204, 208, 210, 212, 214, 216, 218, 220, 222, 226, 224, 230 described with respect to FIGS. 2a and 2b, with the difference being in the position of the cable 218, 318, 418, and 518. In the embodiment of FIGS. 5a and 5b, the cable 518 extends through the lower recessed region 510, then turns upward along the side of the case into the upper recessed region 508, where the cable turns 90 degrees to traverse the upper recessed region 508 toward the device interface 520 reflecting a different location for the device interface 520 than shown with respect to the embodiments of FIGS. 1a-1e, 2a, 2b, 3a, 3b, 4a, and 4b.

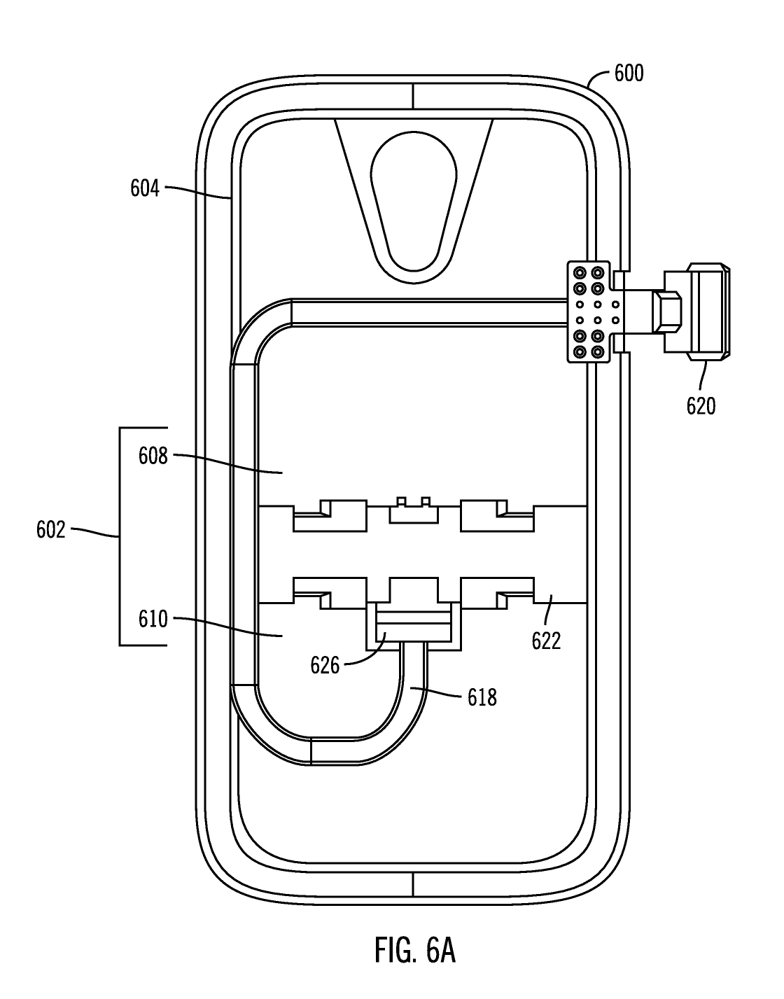

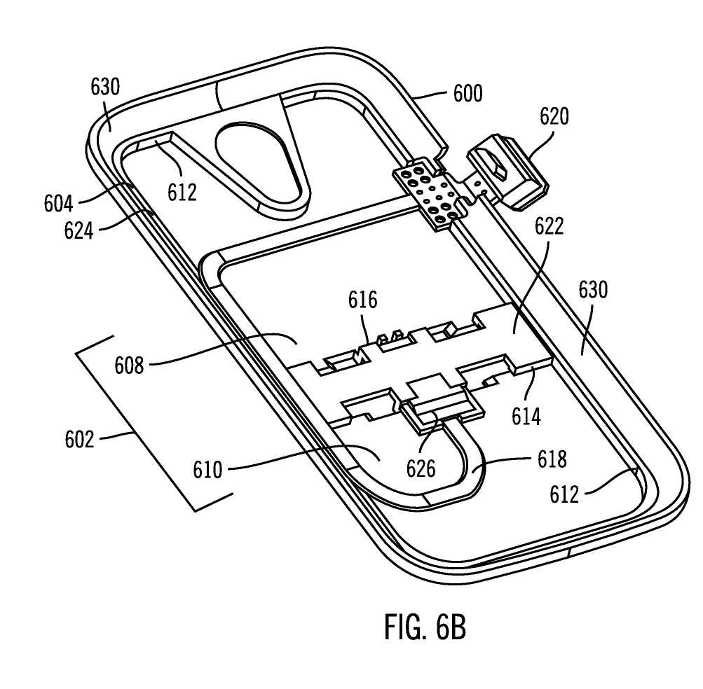

FIGS. 6a and 6b illustrate a sixth embodiment of a back cover portion 600 having elements 600, 602, 604, 608, 610, 612, 614, 616, 618, 620, 622, 626, 624, 630 that respectively correspond to: case elements 500, 502, 504, 506, 508, 510, 512, 514, 516, 518, 520, 522, 526, 524, 530 described with respect to FIGS. 5a and 5b; case elements 400, 402, 404, 408, 410, 412, 414, 416, 418, 420, 422, 426, 424, 430 described with respect to FIGS. 4a and 4b; case elements 300, 302, 304, 308, 310, 312, 314, 316, 318, 320, 322, 326, 324, 330, described with respect to FIGS. 3a and 3b; and case elements 200, 202, 204, 208, 210, 212, 214, 216, 218, 220, 222, 226, 224, 230 described with respect to FIGS. 2a and 2b, with the difference being in the position of the cable 218, 318, 418, and 518. In the embodiment of FIGS. 6a and 6b, the cable 618 extends through the lower recessed region 610, then turns upward along the side of the case into the upper recessed region 608, where the cable turns 90 degrees to traverse the upper recessed region 608 toward the device interface 620 reflecting a different location for the device interface 520 than shown with respect to the embodiments of FIGS. 1a-1e, 2a, 2b, 3a, 3b, 4a, 4b, 5a, and 5b.

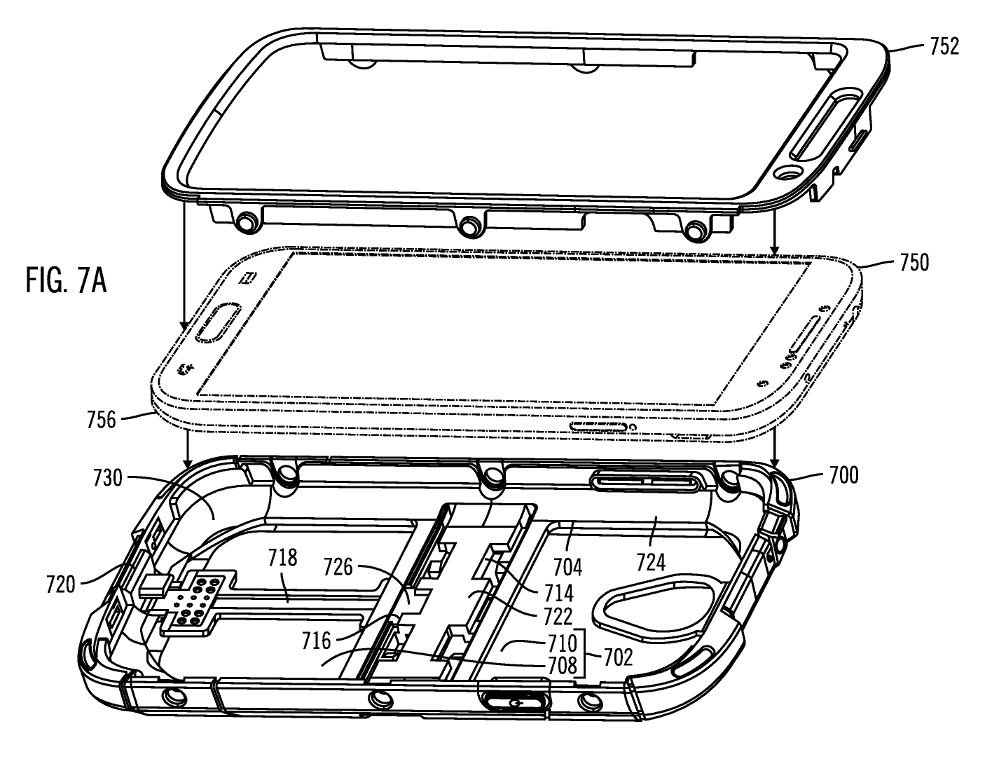

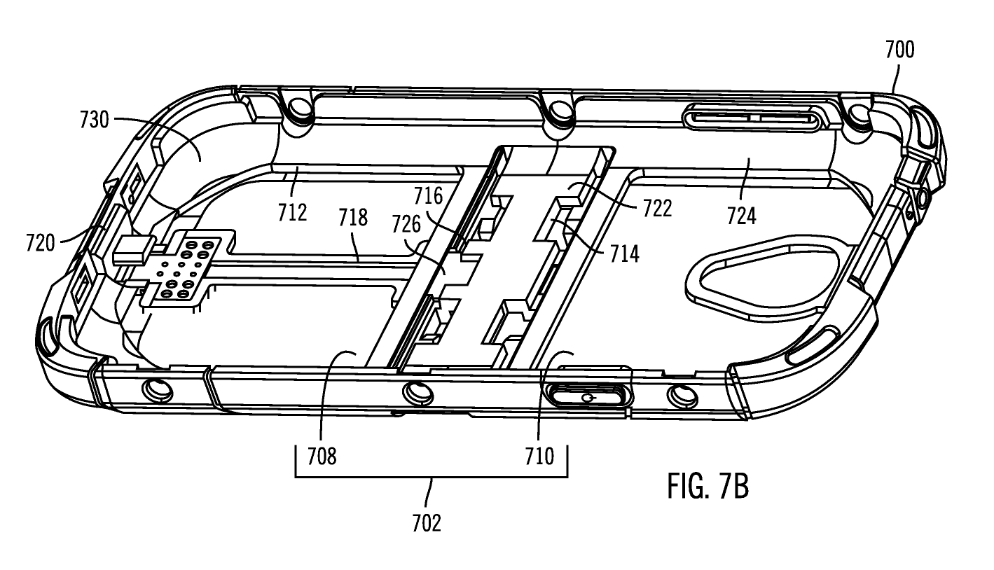

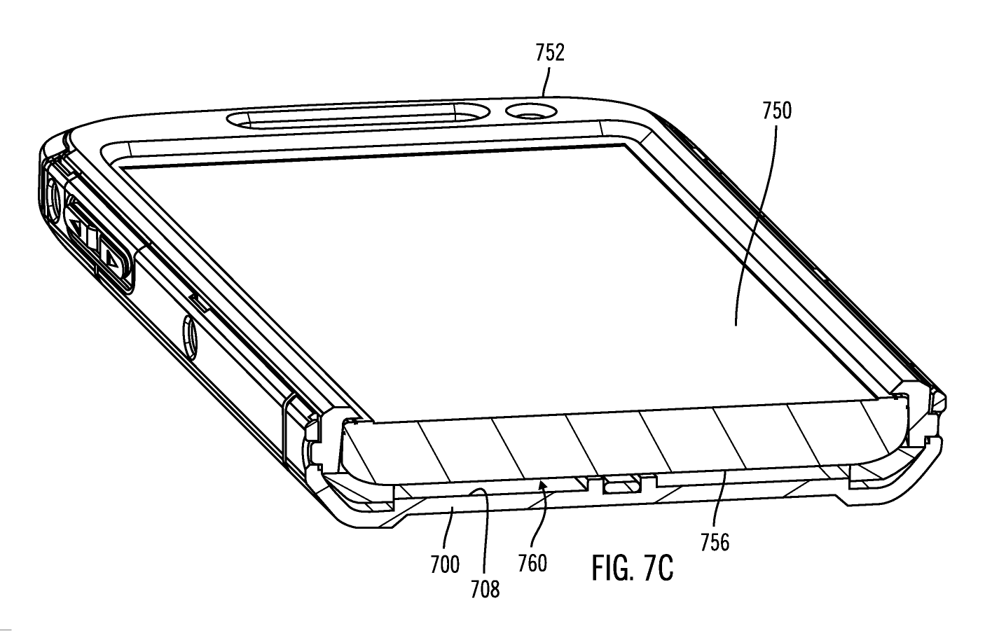

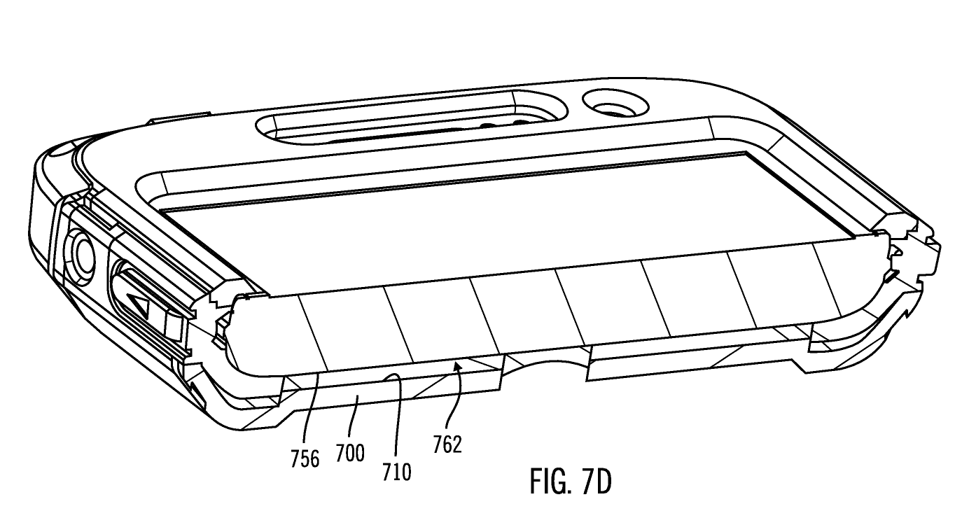

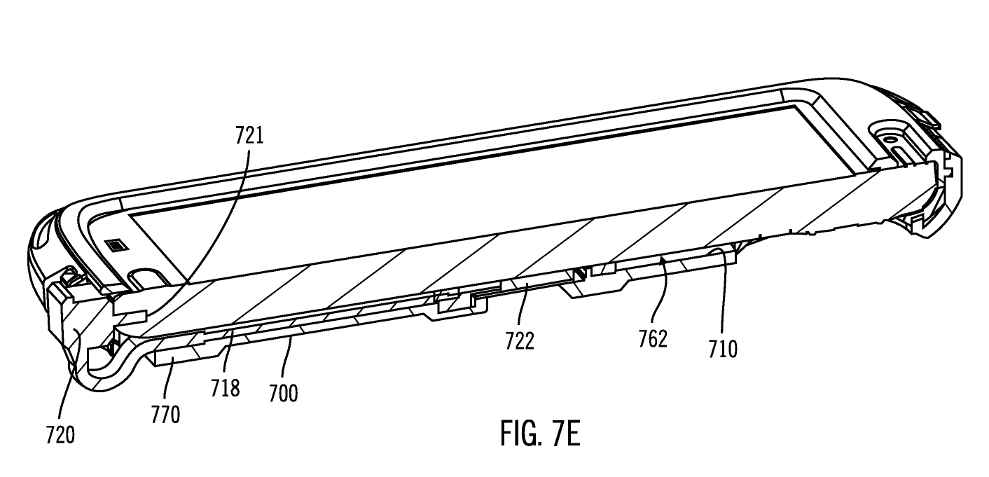

FIG. 7a, 7b, 8a, 8b, 8c illustrate a seventh embodiment of a case. FIG. 7a provides an exploded view of the seventh embodiment of the case showing how a portable electronic device 750, such as a smart phone, is positioned between a front cover portion 752 and a back cover portion 700. FIGS. 7a and 7b show the back cover portion 700 having an inner surface 702 with an elevated rim 704 extending around the inner surface 702. An attachment structure 722, such as described with respect to element 122 in FIGS. 1a-1e, separates the inner surface 702 area into two recessed regions 708, 710. The recessed regions 708, 710 form recessed spaces that are bounded by the inner surface 702, a sidewall 712 (FIG. 2b) of the elevated rim 704, sidewalls 714, 716 (FIG. 2b) of the attachment structure 706 and a back surface 756 of the portable electronic device 721 (FIG. 7e) when coupled with the back cover portion 700. A cable 718 extends from an external device interface 726 through the recessed region 708 (FIG. 7b) to provide an electrical connection between the device interface 721 of the portable electronic device 750 and the external device interface 720. In the embodiment of FIGS. 7a and 7b, the external device interface 720 may not be flexible as shown in the first through sixth embodiments, and may be rigid in the shown position. In the embodiment of FIGS. 7a and 7b, an upper surface 724 of the rim 704 is adapted to contact the portable electronic 750 device when the case 700 is attached to the portable electronic device.

FIGS. 7a and 7b further shows a curved surface 730 extending outward at an angle from a top surface of the rim 704 around the sides of the back cover portion 700. A back surface 756 of the portable electronic device is in contact with the angled surface 730 and the upper surface of the rim 704 when the back portion 700 is coupled to the portable electronic device 750. In alternative embodiments, the surface 730 may have shapes other than curved, such as angular, and may be designed to conform to the back surface and sides of the portable electronic device.

FIGS. 7c, 7d, 7e provide cross sectional views taken of the seventh embodiment of the case described with respect to FIGS. 7a and 7b with the portable electronic device 750 positioned in the case formed by the front cover portion 752 and the back cover portion 700. FIG. 7c shows a space 760 formed between the back surface 756 of the portable electronic device 750 and the recessed region 708 of the inner surface 702. FIG. 7d shows a further cross section taken in the area of recessed region 710 showing the a space 762 formed between the back surface 756 of the portable electronic device 750 and the recessed region 710 of the inner surface 702. The spaces 760, 762 allow the back cover 700 to compress if subject to stress, such as a fall or drop, without contacting the portable electronic device 750 to provide greater protection to the device 750.

FIG. 7e provides a cross sectional view taken along a length of the portable electronic device 750 through the center of the external device interface 720 when positioned in the case formed by the front cover portion 752 and the back cover portion 700. The cable 718 is shown as extending to the external device interface 720. The spaced 762 is also shown in the recessed region 710.

In one embodiment, the back cover portion 700 may be formed of a silicon or soft material fused with the more rigid back cover 700, such as formed with a polycarbonate material, to form a combined uniform shape with varying hardness due to the use of different materials, e.g., a silicon layer on the inner surface 702 and a polycarbonate or more rigid back cover material.

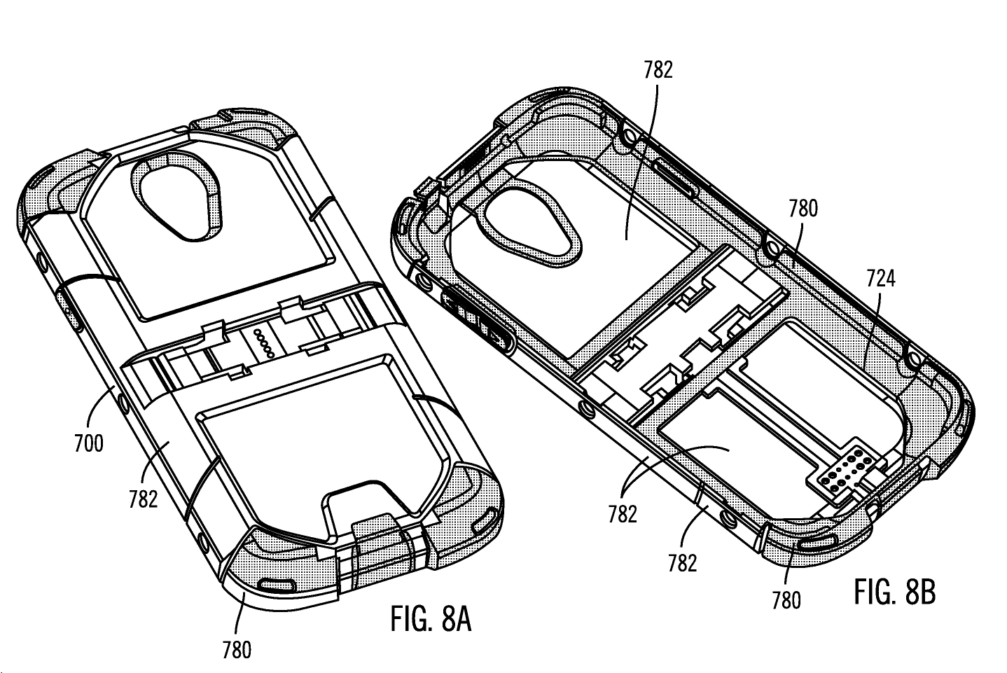

FIGS. 8a and 8b provide an embodiment of the materials that may be used to form the back cover portion for the described embodiments, such as back covers 200, 300, 400, 500, 600 and 700, described with respect to back cover portion 700. The back cover portion 700 may be formed of a first soft layer 780, e.g., silicon, and a second hard layer 782, such as a hardened polycarbonate, where the soft first layer 780 is fused with the second hard layer 782. In this way, the soft first layer 780 provides an elevated layer that forms rims 724, angled surface 730 and other areas of the back cover 700 that are adapted to contact the portable electronic device 750 when engaged with the back cover portion 700. In alternative embodiments, the first soft layer 780 may not be fused with the second hard layer 782, and may instead be adapted to be detached from the cover portion 700 formed by the hard layer. In a yet further alternative embodiment, the first soft layer 780 may be attached to the portable electronic device 750 or part of a sleeve in which the device 750 is inserted. The layers 780 and 782 may be formed from a single piece or from separate pieces fused together.

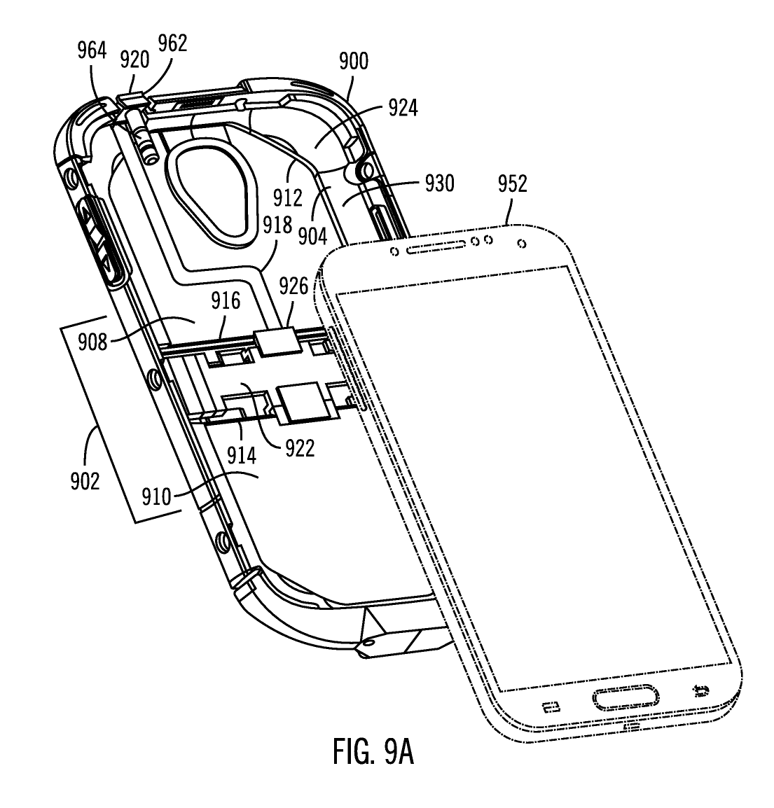

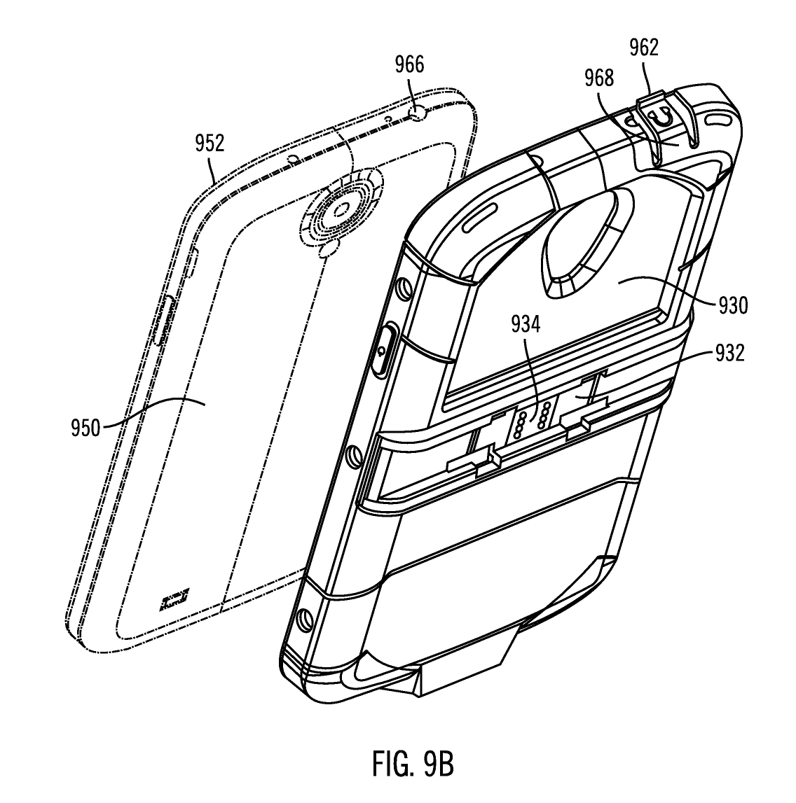

FIGS. 9a and 9b illustrate a ninth embodiment of a back cover portion 900 having elements 900, 902, 904, 908, 910, 912, 914, 916, 918, 920, 922, 924, 926, 930 that respectively correspond to: case elements 600, 602, 604, 608, 610, 612, 614, 616, 618, 620, 622, 626, 624, 630 described with respect to FIGS. 6a and 6b; case elements 500, 502, 504, 508, 510, 512, 514, 516, 518, 520, 522, 526, 524, 530 described with respect to FIGS. 5a and 5b; case elements 400, 402, 404, 408, 410, 412, 414, 416, 418, 420, 422, 426, 424, 430 described with respect to FIGS. 4a and 4b; case elements 300, 302, 304, 308, 310, 312, 314, 316, 318, 320, 322, 326, 324, 330, described with respect to FIGS. 3a and 3b; and case elements 200, 202, 204, 208, 210, 212, 214, 216, 218, 220, 222, 226, 224, 230 described with respect to FIGS. 2a and 2b, with the difference being in the position of the cable 218, 318, 418, and 518.

In FIGS. 9a and 9b, the attachment structure 922, such as described with respect to element 122 in FIGS. 1a-1e, separates the inner surface 202 area into two recessed regions 908, 910. The recessed regions 908, 910 form recessed spaces that are bounded by the inner surface 902, a sidewall 912 (FIG. 9a) of the elevated rim 904, sidewalls 914, 916 (FIG. 9a) of the attachment structure 906 and a back surface 950 (FIG. 9b) of the portable electronic device 952 when coupled with the back cover portion 900. In the embodiment of FIG. 9a, an upper surface 924 of the rim 904 is adapted to contact the portable electronic device when the case 900 is attached to the portable electronic device.

A cable 918 extends from an external device interface 926 through the recessed region 908 and connects to an audio interface 920. The audio interface 920 includes a movable flap 962 having an audio connector 964, a male connector, extending downward into the case 920. The audio connector 964 is adapted to fit into an audio socket 966 of the portable electronic device 952 (FIG. 9b). The audio connector 964 may have portions to allow for microphone audio signals to be transmitted to the portable electronic device 952 from an external device, such as a microphone, or audio jack input coupled to the attachment structure 922. The audio connector 964 may also have portions for the transmission of ground, left and right audio signals from the portable electronic device 952 through the cable 918 to an external device coupled to the attachment structure 922 and capable of receiving audio input from the portable electronic device 952. In further embodiments, the connector 964 may also be capable of transmitting other types of data, such as video, documents, non-audio files, etc. through the audio interface 920 and external device interface 926 to the external device. The term “data” as used herein refers any type of transferrable data, such as audio, video, computer programs, structured documents, markup language documents, database files, text, encrypted data, compressed data, etc.

FIG. 9b shows the movable flap 962 formed of a rubber or silicon material 968 that is formed on the back of the case 900. The movable flap 962 has electrical connectors to allow transmission of audio signals between the audio connector 964 and the cable 918. The movable flap 962 and attached audio connector 964 may move outward from the case 900 to cause the audio connector 964 to be positioned orthogonal with respect to a plane of the case 900, 930 surface. This allows for the audio connector 964 to be removed from the audio socket 966. The movable flap 962 may then be directed toward the audio socket 966 so that the audio connector 64 can be positioned inside the audio socket 966. FIGS. 9a and 9b show the movable flap in an extended state where force is not exerted on the movable flap 962

FIG. 9b shows an outer surface 930 of the cover portion 900 and outer side 932 of the attachment structure 922. The external interface 926 (FIG. 9a) has an external connector 934 (FIG. 9b) on the outer side 932 of the attachment structure 922, shown as contact pads in FIG. 9b, to electrically couple to an external electronic device or cable or wire connected to the external electronic device. The external connector 934 is shown comprising a certain number of contact pads. In alternative embodiments, there may be a different arrangement and/or number of contact pads as well as an different connector configuration, such as a male or female connection port.

The cable 918 (FIG. 9a) on the inner surface 902 includes electrical wiring to electrically connect the audio interface 920 that is designed to connect to an audio socket 966 on the portable electronic device 950. The audio interface 920 is in electrical communication with the external interface 934 (FIG. 1b) via the cable 918 to allow the transmission of audio signals among the interfaces 920, 926, and 934.

The cover portions 100, 150, 200, 300, 400, 500, 600, 700, and 900 in the embodiments may be formed of a polycarbonate or other material, such as a flexible polyurethane material, or a combination of different materials. In further embodiments, the cover portions may be formed of multiple materials, such as a silicon layer on the inner surface of the back cover fused with a more rigid polycarbonate, metal or other material for the back cover, such as shown in FIGS. 8a and 8b.

The cable 128, 218, 318, 418, 518, 618, 718, 918 may run along the inner surface 102, 202, 302, 402, 502, 602, 702, 902 in the recessed regions as shown in the embodiments. In alternative embodiments, the cable may be embedded within the cover portion material as opposed to extending on the inner surface of the case portion. In certain embodiments where the cable is embedded in the cover portion, no portion of the cable may appear on the inner surface of the cover portion. In described embodiments, only one cable is shown. In further embodiments there may be multiple cables between the interfaces or additional interfaces than shown.

The case of the described embodiments may accommodate different locations of the portable electronic device interface, e.g., 136, 220, 320, 420, 520, 620, 720, 920, which is determined by where the portable electronic device manufacturer locates their device interface. However, the case manufacture may place the attachment structure 122, 222, 322, 422, 522, 622, 722, 922 at an optimal location for the attachment irrespective of where the portable electronic device manufacturer located the device interface because a cable 128, 218, 318, 418, 518, 618, 718, 918 electrically couples the portable electronic device and external device interfaces in the case.

Described embodiments provide a case for a portable electronic device having a cover portion to provide for a cable to electrically couple a first interface at a first location on the cover portion adapted to couple to the portable electronic device and a second interface at a second location on the cover portion to electrically couple to the external electronic device. Described embodiments allow the case to provide electrical coupling between an external electronic device and the portable electronic device in the case to allow for the external device interface and portable electronic device interface to be at different locations to accommodate the structural and manufacturer requirements for the locations of those electrical interfaces.

Terms such as “top”, bottom”, “upper”, “lower”, “rear”, “front”, “back”, “outer”, “inner”, “bottom”, “left”, and the like may be used for descriptive purposes only and are not to be construed as limiting. Embodiments may be manufactured, used, and contained in a variety of positions and orientations.

In the foregoing Detailed Description, various features are grouped together for the purpose of streamlining the disclosure. This method of disclosure is not to be interpreted as reflecting an intention that the claimed embodiments of the invention require more features than are expressly recited in each claim. Rather, as the following claims reflect, inventive subject matter may lie in less than all features of a single disclosed embodiment. Thus the following claims are hereby incorporated into the Detailed Description, with each claim standing on its own as a separate preferred embodiment.

While certain exemplary embodiments have been described above and shown in the accompanying drawings, it is to be understood that such embodiments are merely illustrative and not restrictive, and that embodiments are not restricted to the specific constructions and arrangements shown and described since modifications may occur to those having ordinary skill in the art.

What is claimed:

1. A case for a portable electronic device including a first surface, a second surface, and sides between the first surface and the second surface, wherein the portable electronic device has an input socket and is adapted to electrically connect to an external electronic device, comprising:
a cover portion adapted to couple to the first surface of the portable electronic device;
a first interface at a first location on the cover portion to electrically couple to the input socket of the portable electronic device;
a second interface at a second location on the cover portion adapted to electrically couple to the external electronic device; and
a cable coupled to the first and second interfaces adapted to transmit data between the first interface and the second interface.

2. The case of claim 1, wherein the cover portion includes an inner surface opposite the portable electronic device and an outer surface, wherein the cable extends through the inner surface.

3. The case of claim 2, further comprising:
an elevated portion extending outward from a portion of the inner surface and having a sidewall defining a surface orthogonal to the inner surface; and
a recessed region defined by the sidewall of the elevated portion and the inner surface, wherein the cable extends through the recessed region.

4. The case of claim 2, wherein the cover portion includes sides, wherein the first location is on one of the sides and wherein the second location is between the sides on the inner surface.

5. The case of claim 2, wherein the second interface includes:
a first connector opening at the inner surface and coupled to the cable; and
a second connector opening at the outer surface of the case, wherein the second connector is adapted to couple to the external electronic device.

6. The case of claim 1, wherein the input socket comprises a female audio socket on the portable electronic device, and wherein the first interface includes a male audio connector to fit into the female audio socket.

7. The case of claim 6, wherein the first interface includes a movable flap connected to the cover portion, wherein the male audio connector extends from the movable flap, wherein the movable flap includes electrical connector to provide electrical communication of data from the male audio connector to the cable.

8. The case of claim 7, wherein the movable flap is formed of an elastic material that extends along an outer surface of the case.

9. The case of claim 7, wherein the movable flap is attached to a side wall of the case.

10. The case of claim 1, wherein the first and second interfaces and cable communicate sound signals between the portable electronic device and the external device.

11. The case of claim 1, wherein the cover portion comprises a first cover portion and the first surface comprises a back surface of the portable electronic device and the second surface of the portable electronic device comprises a front surface having user interface controls of the portable electronic device, further comprising:
a second cover portion adapted to couple to the front surface of the portable electronic device and adapted to couple to the first cover portion, wherein the first and second cover portions coupled together form the case.

12. A case for a portable electronic device including a first surface, a second surface, and sides between the front surface and the back surface, wherein the portable electronic device includes an input socket and is adapted to electrically connect to an external electronic device and wherein the case is adapted to attach to an external structure, comprising:
a cover portion having an inner surface and outer surface, wherein the inner surface is adapted to couple to the first surface of the portable electronic device;
a first interface at a first location on the cover portion adapted to electrically couple to the input jack of the portable electronic device;
a second interface at a second location on the cover to electrically couple to the external electronic device;
an attachment structure formed on the outer surface of the cover portion and adapted to attach the cover portion to the external structure, wherein the external electronic device is electrically coupled to the second interface when the external structure is coupled to the attachment structure; and
a cable coupled to the first and second interfaces adapted to transmit data between the first interface and the second interface.

13. The case of claim 12, further comprising:
a housing within the attachment structure, wherein the housing includes the second interface.

14. The case of claim 13, wherein the attachment structure has an inner surface on the inner surface of the cover portion and an outer surface on the outer surface of the cover portion, wherein the second interface is coupled to the attachment structure, and wherein the second interface includes:
a first connector opening into the inner surface of the cover portion and coupled to the cable; and
a second connector opening onto the outer surface of the attachment structure and adapted to couple to the external electronic device.

15. The case of claim 12, wherein the portable electronic device input socket comprises a female audio socket, and wherein the first interface includes a male audio connector to fit into the female audio socket, wherein the female audio socket is capable of transmitting.

16. The case of claim 15, wherein the first interface includes a movable flap connected to the cover portion, wherein the audio connector extends from the movable flap, wherein the movable flap includes electrical connector to provide electrical communication of audio signals from the audio connector to the cable.

17. A case for a portable electronic device including a first surface, a second surface, and sides between the front surface and the back surface, wherein the portable electronic device has an input socket and is adapted to electrically connect to an external electronic device, comprising:
a cover portion adapted to attach to the portable electronic device, wherein the cover portion has an inner surface adapted to contact the first surface of the portable electronic device and an outer surface;
an elevated rim located on the inner surface of the cover portion, wherein the elevated rim has a sidewall extending from the inner surface to an upper surface of the elevated rim;
a first interface on a side of the cover portion adapted to electrically couple to the input socket of the portable electronic device;
a recessed region defined by the sidewalls of the elevated rim and the inner surface of the cover portion;
a second interface having a connector at on the outer surface of the cover portion, wherein the connector is adapted to couple to the external electronic device; and
a cable coupled to the first interface and the second interface, wherein the cable extends through the recessed region.

18. The case of claim 17, wherein the elevated rim is positioned along a portion of at least one side of the cover portion, wherein the sidewall comprises a first sidewall, further comprising:
a second sidewall extending from an upper surface of the elevated rim at an outer side of the upper surface of the elevated rim, wherein the first sidewall is formed on an inner side of the elevated rim and extends from the upper surface of the elevated rim towards the inner surface of the cover portion, wherein the second sidewall and the upper surface of the elevated rim are adapted to couple to the first surface and a portion of the sides of the portable electronic device, wherein the recessed region is further defined by the first surface of the portable electronic device, the first sidewall of the elevated rim, and the inner surface.

19. The case of claim 18, wherein the second sidewall forms an angled surface extending outward from the outer side of the elevated rim.

20. The case of claim 18, wherein the cover portion has a first side opposite a second side and third side opposite a fourth side, wherein the second interface is located on the inner surface of the cover portion between the first and the second sides and between the third and the fourth sides, wherein the first interface is located on the first side, and wherein the cable extends through the recessed region between the first and the second interfaces.

21. The case of claim 20, wherein the portable electronic device input socket comprises a female audio socket, and wherein the first interface includes a male audio connector to fit into the female audio socket.

22. The case of claim 21, wherein the first interface includes a movable flap connected to the cover portion, wherein the male audio connector extends from the movable flap, wherein the movable flap includes electrical connector to provide electrical communication of audio signals from the male audio connector to the cable.

23. A method for attaching a case to a portable electronic device, wherein the portable electronic device has a first surface, a second surface, and sides between the first surface and the second surface, and an input socket, comprising:
attaching a cover portion to the first surface of the portable electronic device;
adjusting a first interface at a first location on the cover portion to engage the input socket of the portable electronic device;
coupling an external device to a second interface at a second location on the cover portion adapted to electrically couple the portable electronic device and the external electronic device, wherein aa cable coupled to the first and second interfaces is adapted to transmit data between the first interface and the second interface.

24. The method of claim 23, wherein the input socket comprises a female audio socket on the portable electronic device, and wherein the first interface includes a male audio connector to fit into the female audio socket, wherein adjusting the first interface to engage the input socket comprises positioning the male audio connector in the female audio socket.

25. The method of claim 24, wherein the first interface includes a movable flap connected to the cover portion, wherein the male audio connector extends from the movable flap, wherein the movable flap includes electrical connector to provide electrical communication of data from the male audio connector to the cable, and wherein the positioning the male audio connector further comprises manipulating the movable flap to fit the male audio connector in the female audio socket.
